(19) United States
(12) Patent Application Publication
(10) Pub. No.: US 2013/0140066 A1
(43) Pub. Date: Jun. 6, 2013

(54) CU ALLOY INTERCONNECTION FILM FOR TOUCH-PANEL SENSOR AND METHOD OF MANUFACTURING THE INTERCONNECTION FILM, TOUCH-PANEL SENSOR, AND SPUTTERING TARGET

(71) Applicant: Kabushiki Kaisha Kobe Seiko Sho (Kobe Steel, Ltd.), Kobe-shi (JP)

(72) Inventors: Hiroyuki Okuno, Kobe-shi (JP); Aya Miki, Kobe-shi (JP); Toshihiro Kugimiya, Kobe-shi (JP)

(73) Assignee: Kabushiki Kaisha Kobe Seiko Sho (Kobe Steel, Ltd.), Kobe-shi (JP)

(21) Appl. No.: 13/661,902

(22) Filed: Oct. 26, 2012

(30) Foreign Application Priority Data
Dec. 6, 2011 (JP) 2011-266690
Dec. 6, 2011 (JP) 2011-266691

(51) Int. Cl. H05K 1/09; C23C 14/35; C23C 14/14

(52) U.S. Cl. 174/257; 204/298.13; 204/192.29

(57) ABSTRACT

Provided is a Cu alloy interconnection film for touch-panel sensors, which excels in oxidation resistance and adhesion properties, and is low in electrical resistance. The interconnection film contains at least one alloy element selected from a group consisting of Ni, Zn, and Mn by 0.1 to 40 atom % in total, and the remainder contains Cu and inevitable impurities. Alternatively, the interconnection film is made of a Cu alloy containing at least one element selected from the group consisting of Ni, Zn, and Mn. In this case, if the Cu alloy contains one element, Ni is contained by 0.1 to 6 atom %, or Zn is contained by 0.1 to 6 atom %, or Mn is contained by 0.1 to 1.9 atom %. On the other hand, if two or more alloy elements are contained, the alloy elements are contained by 0.1 to 6 atom % in total (wherein, Mn is contained by [((6−x)×2)/6] atom % or less if Mn is contained; here, x is a total adding amount of Ni and Zn).

### CROSS-REFERENCE TO RELATED APPLICATION(S)

The application claims priority under 35 U.S.C. §119 to Japanese Patent Applications No. 2011-266690 and 2011-266691, which were filed on Dec. 8, 2011, the entire disclosure of which is hereby incorporated by reference.

### TECHNICAL FIELD

The present invention relates to a Cu alloy interconnection film for a touch-panel sensor connected with a transparent conductive film, a method of manufacturing the Cu alloy interconnection film, a touch-panel sensor using the Cu alloy interconnection film, and a sputtering target for forming the Cu alloy interconnection film.

### BACKGROUND OF THE INVENTION

Touch-panel sensors, which are arranged on a front surface of an image display device and used as an input switch formed integrally with the image display device, have been widely used due to the user-friendliness for mobile phones and tablet PCs in addition to bank ATMs, ticketing machines, car navigation display, operation screens of copy machines, and so on. A method of sensing a location of input (input point) includes resistive, capacitive, optical, ultrasonic surface acoustic wave and piezoelectric methods. Among these, the capacitive sensing has been used for mobile phones and tablet PCs because it can provide good responses with a simple and low-cost structure.

The capacitive-type touch-panel sensor has a structure comprising two kinds of transparent conductive films intersecting perpendicularly with each other via a glass substrate, a film substrate, an organic film, an SiO₂ film, etc. When surface of a touch-panel sensor of such a structure is touched with a finger or the like, a touched location (input point) is sensed based on a variation in the capacitance between the transparent conductive films.

In a process of manufacturing the touch-panel sensor described above, interconnections such as wiring for connecting the transparent conductive films with a control circuit, and wiring for connecting between the transparent conductive films have been generally formed by printing conductive paste, such as silver paste, or conductive ink, with a printing method, such as ink-jet method. However, as for the touch panel of, for example, the capacitive type which requires fine wiring dimensions, the above techniques cannot be used and, therefore, a pattern formation by sputtering film formation and lithography dominates the market. As for a material of the interconnection, Al- and Cu-alloys have been evaluated other than Ag-alloys. However, Ag alloys are costly as the material, while Al alloys require a laminated structure with Mo or the like because of problems related to a chemical fluid tolerance and a contact resistance with transparent conductive films made of, for example, indium tin oxide (ITO).

Although Cu does not cause such problems, Cu oxidizes easily to form a Cu oxide film and, therefore, causes other problems such as a discoloration, an increase in resistance, and a membranous loss due to oxidization on the surface of Cu during the manufacturing process. For a touch-panel sensor in particular, when the oxidization of the interconnection film itself progresses resulting in increase the oxide film thickness, it induces an increase in connection resistance between the transparent conductive film and the interconnection film, resulting in signal delays.

JP4065959B2 and JP2007-017926A disclose Cu alloys excelling in oxidation resistance in the art of display devices such as liquid crystal displays. In this art, an improvement of the oxidation resistance is attained by utilizing a heat history with at least 200° C. or higher in order to form a TFT, silicone oxide, or silicone nitride on a substrate, and precipitating additive element(s) from the Cu alloy film to form an oxide layer of an alloy element. However, since a process at or above 200° C. is not required in the manufacturing process of the touch panel, it is not desirable in terms of productivity or a protection of the resin substrate to perform the high-temperature heat treatment disclosed in JP4065959B2 and JP2007-017926A.

Moreover, because interconnection films using pure Ag, Ag alloy(s), pure Al, or Al alloy(s) have poor adhesion properties to the transparent conductive films, etching for processing the interconnection film into a wiring shape is difficult, and defects due to, for example, exfoliation or disconnection are caused.

On the other hand, as for pure Cu, although neither the problem of contact resistance nor the problem of medical fluid tolerance will not arise, it may have a problem in the adhesion properties to the transparent conductive films. Against the problem of the adhesion properties of the Cu wiring, for example, JP2008-166742A, JP2009-169268A, JP2010-103331A, JP2010-258347A, JP2010-258346A, and JP2011-048323A disclose, in the art of display devices such as liquid crystal displays, Cu alloys excelling in the adhesion properties to the glass substrate which is a base material of the Cu interconnection film or an interlayer insulation film. However, in the art of display devices, since the transparent conductive films are formed after processing it into the Cu wiring, it is not necessary to consider the adhesion properties between the Cu interconnection film and the transparent conductive films at the time of the Cu interconnection film processing which pose a problem in the art of touch panels. Therefore, the adhesion properties between the Cu wiring and the transparent conductive film have never been considered.

### SUMMARY OF THE EMBODIMENT

The present application is made in view of the above situations, and it provides a interconnection film for touch-panel sensors excelling in adhesion to transparent conductive films, as well as excelling in an oxidation resistance, while maintaining electrical resistivity low. The invention also provides a method of manufacturing the interconnection film, a touch-panel sensor using the interconnection film, and a sputtering target suitable for forming the interconnection film.

According to one aspect of the invention, a interconnection film for a touch-panel sensor, having a transparent conductive film and connected with the transparent conductive film is provided. The interconnection film is a Cu alloy film, and it excels in oxidation resistance. The film contains at least one alloy element selected from a group consisting of Ni, Zn, and Mn by 0.1 to 40 atom % in a total amount, and the remainder contains Cu and inevitable impurities.

The interconnection film includes a first layer made of a Cu alloy containing at least one alloy element selected from the group consisting of Ni, Zn, and Mn by 0.1 to 40 atom % in a total amount and, thus, excelling in oxidation resistance. The interconnection film also includes a second layer made of pure Cu or a Cu alloy mainly containing Cu, and the Cu alloy having a lower electrical resistivity as compared with the first layer. Thus, the interconnection film has a laminated structure of the first layer and the second layer, and the first layer and/or the second layer are connected with the transparent conductive film.

The first layer may contain at least one alloy element selected from the group consisting of Ni, Zn, and Mn by 0.1 to 30 atom % in a total amount, and the first layer may be connected with the transparent conductive film.

The first layer may have a thickness of 5 to 100 nm.

According to another aspect of the invention, a interconnection film made of a Cu alloy containing at least one alloy element selected from a group consisting of Ni, Zn, and Mn is provided. If one alloy element is contained, Ni is contained by 0.1 to 6 atom %, or Zn is contained by 0.1 to 6 atom %, or Mn is contained by 0.1 to 1.9 atom %. On the other hand, if two or more of the alloy elements are contained, the alloy elements are contained by 0.1 to 6 atom % in a total amount. In this case, Mn is contained by [((6−x)×2)/6] atom % or less if Mn is contained (here, x is a total adding amount of Ni and Zn in the formula).

According to another aspect of the invention, a touch-panel sensor is provided, which includes any one of the Cu alloy interconnection films.

The transparent conductive film may be formed on a film substrate.

According to another aspect of the invention, a sputtering target for forming the interconnection film is provided. The sputtering target contains at least one alloy element selected from the group consisting of Ni, Zn, and Mn by 0.1 to 40 atom % in total, and the remainder contains Cu and inevitable impurities.

Alternatively, the sputtering target may contain at least one alloy element selected from the group consisting of Ni, Zn, and Mn by 0.1 to 30 atom % in total, and the remainder may contain Cu and inevitable impurities.

According to another aspect of the invention, a method of manufacturing the interconnection film is provided. The method includes forming the interconnection film (Cu alloy film) having the component composition described above, and heating the interconnection film at a temperature below 200° C. for 30 seconds or longer.

According to the present invention, since the Cu alloy containing a predetermined amount of the oxidation resistance enhancing element(s) is used as the interconnection film for touch-panel sensors, the Cu alloy interconnection film can demonstrate effects excelling in the oxidation resistance. In addition, since the Cu alloy containing a predetermined amount of the adhesion enhancing element(s) may be used as the alloy element(s), the Cu alloy may also demonstrate excellent adhesion properties to the transparent conductive film and/or excellent electrical resistance. In addition, the Cu alloy (first layer and second layer) having the laminated structure of the Cu alloy film (first layer) excelling in the adhesion properties and the oxidation resistance, and the second layer having the lower electrical resistivity than the first layer can demonstrate more excellent adhesion properties and more excellent oxidation resistance as well as lower electrical resistivity.

Therefore, according to the present invention, the Cu alloy interconnection film for touch-panel sensors and the touch-panel sensor using the interconnection film can be provided, which can resolve problems of conventional interconnection films where adhesion properties and oxidation resistance are low, while maintaining the electrical resistivity low. Further, the present invention also provides the method of manufacturing the Cu alloy interconnection film having such effects, and the sputtering target suitable for the formation of the interconnection film.

### BRIEF DESCRIPTION OF THE DRAWINGS

The present disclosure is illustrated by way of example and not by way of limitation in the figures of the accompanying drawings, in which the like reference numerals indicate like elements and in which:

FIG. 1 is a cross-sectional view schematically showing a configuration of a second embodiment of the invention; and

FIG. 2 is a cross-sectional view schematically showing a configuration of a fourth embodiment of the invention.

### DETAILED DESCRIPTION

The present inventors conducted careful research in order to provide a interconnection film excelling in oxidation resistance in addition to having an electrical resistance required for touch-panel sensor wiring, as well as to provide a touch-panel sensor using the interconnection film.

As a result, it was found that the interconnection film to be connected with a transparent conductive film is preferably made of a Cu alloy containing at least one of alloy elements (i.e., enhancing element(s) of the oxidation resistance) selected from a group consisting of Ni, Zn, and Mn. Particularly, it was found that the alloy element(s) (Ni, Zn, and/or Mn) contained in the Cu alloy form a concentrated layer at the surface of the Cu alloy film, and this concentrated layer enhances the oxidation resistance.

It is considered that the concentrated layer is formed by alloy element(s) (e.g., Ni) in the Cu alloy which exceed solid solubility limits are spread and concentrated over the surface of the Cu alloy interconnection film by, for example, heat treatment. In addition, it was found that Zn and Mn can form concentrated layers, similar to Ni.

The term “concentrated layer” as used herein refers to a formation of a concentrated layer area on the surface of the interconnection film, where the concentrated layer area is higher in alloy content than the entire Cu alloy film. The alloy element includes at least one alloy element selected from a group consisting of Ni, Zn, and Mn.

Hereinafter, several embodiments excelling in the oxidation resistance will be described in detail. Note that the term “Cu alloy film” as used herein refers to a film in a state where the film is formed by sputtering or the like, and the term “Cu alloy interconnection” as used herein refers to the Cu alloy film which is formed in a interconnecting shape by etching or the like. Also, note that both the terms may be comprehensively represented herein by a term “Cu alloy interconnection film.” Next, a first embodiment of the invention is described.

### First Embodiment

### [Cu Alloy Containing Predetermined Amount of At Least One Alloy Element Selected From Group Consisting of Ni, Zn, and Mn: Monolayer]

The oxidation resistance is enhanced herein by containing, as enhancing element(s) of the oxidation resistance, a predetermined amount of at least one alloy element selected from a group consisting of Ni, Zn, and Mn.

These alloy elements are selected from elements which dissolve in the Cu alloy but do not dissolve in the copper oxide film. Thus, it was found that, when the Cu alloy where the alloy elements are dissolved oxidizes, since the alloy elements do not dissolve in the Cu oxide film, the alloy elements are swept out under an interface of the Cu oxide film generated by the oxidization to form a concentrated layer. In addition, since such a concentrated layer of the alloy elements minimizes a growth of the Cu oxide film, an increase of the electrical resistivity of the Cu alloy interconnection film can be suppressed. As a result of the present applicants' examination, it was found that a sufficient concentrated layer which contributes to the improvement in the oxidation resistance cannot be formed without Ni, Zn, or Mn. For example, if Mg dissolves in the Cu alloy but does not dissolve in the Cu oxide film, similar to Ni, and in a case where only a heat history below 200° C. can be applied, the concentrated layer is not fully formed and, thus, a growth of the Cu oxide film cannot be suppressed, resulting in an increase of the electrical resistivity of the Cu alloy film.

The oxidation resistance enhancing elements described above are preferably Ni and Zn, and is more preferably Ni. Ni develops very strongly the concentrating effects at the interface described above, and therefore, Ni is an element which forms a thin oxide layer and can obtain a major improvement in the oxidation resistance.

The concentrated layer where at least one element selected from a group consisting of Ni, Zn, and Mn is concentrated at the interface can be obtained preferably by heating at below 200° C. for more than 30 seconds after the Cu alloy film formation by sputtering. Such a heat treatment allows the alloy element to easily spread and concentrate on the surface of the Cu alloy interconnection film. Conditions of the heat treatment will not be particularly limited as long as the desired concentrated layer can be obtained, and they can suitably be adjusted in accordance with a heat resistance of the substrate, an efficiency of the process, etc.

Note that the heat treatment may be carried out for the purpose of forming the concentrated layer, or may be carried out such that a heat history after the formation of the Cu alloy film (e.g., a process for baking the resist layer) meets the temperature and the time described above.

The content of the element(s) is 0.1 atom % or more in a total amount (an individual content of the element if the number of elements is one). If the content of the element(s) is below 0.1 atom %, the formation of the concentrated layer will not be satisfactory, and an adequate oxidation resistance cannot be achieved. Although more content of the element(s) effects more in the improvement of the oxidation resistance, if the total content of the element(s) exceeds 40 atom %, a microfabrication will be difficult because of an increase in undercut at the time of etching into the wiring shape, and a generation of residues. Further, an electrical resistivity of the Cu alloy interconnection film itself will be higher, increasing signal delays and power loss. In terms of the improvement of oxidation resistance, a lower limit of the total content of the element(s) is preferably 0.3 atom %, more preferably 0.7 atom %, and still more preferably 1.0 atom %. In terms of the electrical resistivity or the like, an upper limit of the total content is preferably 15 atom %, more preferably 10 atom %, and still more preferably 5 atom %.

The Cu alloy interconnection films used for the present invention contain the element(s) described above, and the remainder contains Cu and inevitable impurities. The content of each alloy element in the Cu alloy interconnection film can be determined by, for example, ICP emission spectrometry.

In the present invention, the Cu alloy interconnection film described above may be solely used as the wiring material, or the wiring material may be formed in a laminated structure of the Cu alloy interconnection film (hereinafter, referred to as a “first layer”) containing the element(s) described above, and a Cu alloy interconnection film (hereinafter, referred to as a “second layer”) that is connected with the transparent conductive film and is lower in the electrical resistivity than the first layer (i.e., a second embodiment). Hereinafter, the second embodiment of the invention is described.

### Second Embodiment

[Cu Alloy Interconnection film Comprising Cu Alloy (First Layer) Containing The Above Predetermined Amount (0.1 to 40 atom %) of At Least One Element Selected From Group Consisting of Ni, Zn, and Mn, And Second Layer Made of Cu Alloy Having Lower Electrical Resistivity Than First Layer: Laminated Structure]

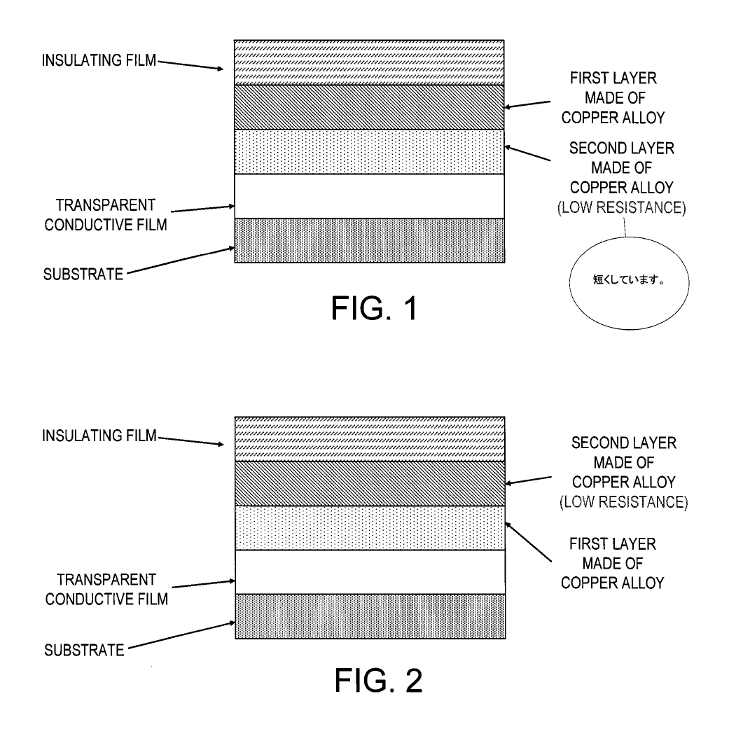

The electrical resistivity will also increase as the adding amount of the alloy element(s) to the Cu alloy film, which contribute to the improvement of the oxidation resistance as described above, is increased. For this reason, a reduction of the electrical resistivity of the entire Cu alloy interconnection film can be achieved by intervening between the transparent conductive film and the first layer such a Cu alloy interconnection film (second layer) having a lower electrical resistivity than the Cu alloy interconnection film (first layer) excelling in the oxidation resistance (refer to FIG. 1). Thus, by constructing the Cu alloy interconnection film in the laminated structure of the first layer and the second layer, the maximum effect of an original Cu property, which is low in the electrical resistivity, can be exerted effectively, while further increasing the oxidation resistance which is a disadvantage of Cu. The Cu alloy which constitutes the first layer is similar herein to the Cu alloy of the first embodiment.

The term “Cu alloy having the lower electrical resistivity than the first layer” which constitutes the second layer also includes pure Cu, where the second layer is suitably controlled in the type(s) and/or the content of the alloy element(s) so that the electrical resistivity of the second layer becomes lower than the first layer made of the Cu alloy containing the oxidation resistance enhancing element. The element with a low electrical resistivity (preferably, as low as pure Cu) can be readily selected from known elements with reference to values described in literatures. However, since the electrical resistivity can be reduced even for a high resistivity element if its content can be lessened (in general, about 0.05 to 1 at %), the alloy element applicable to the second layer is not necessarily limited to elements with a low electrical resistivity. Specifically, in terms of suppressing the signal delays and the power loss due to the wiring resistance of the touch panel, the electrical resistivity of the second layer is preferably 10 μΩcm or lower, more preferably 5 μΩcm or lower, and still more preferably 3.5 μΩcm or lower, for example.

As such a second layer, pure Cu, Cu—Ca, Cu—Mg or the like may be suitably employed. For example, since the electrical resistance can be kept low if the total amount of the oxidation resistance enhancing elements, which are of Ni, Zn, and Mn, constituting the second layer, is 1.5 atom % or less in general, at least one of the elements may also be used.

In addition, the alloy element(s) applicable to the second layer may contain a gas component of oxygen gas or nitrogen gas, and may be employed in the form of Cu—O or Cu—N, for example. Note that the Cu alloy having the lower electrical resistivity than the first layer contains the applicable element(s) described above, and the remainders are substantially Cu and inevitable impurities.

If the second layer is laminated with the first layer to constitute the Cu alloy interconnection film, it is desirable because the electrical resistivity can be reduced by the second layer. Thus, by the second layer alone with a low electrical resistance, the second layer is in a state in which it can be easily oxidized similar to the conventional Cu interconnection films. However, in this embodiment, since the second layer underlies the first layer, the oxidization of the second layer can be prevented by the effects of the first layer.

Note that an arbitrary third layer may also be provided between the second layer and the transparent conductive film. For example, in order to enhance the adhesion properties between the second layer and the transparent conductive film, a layer which contributes to the enhancement of adhesion may be provided.

As described above, although the Cu alloy interconnection film of the present invention is comprised of the Cu alloy monolayer containing the oxidation resistance enhancing element(s) (first embodiment), or is constructed in the laminated structure of the first layer and the second layer in terms of reducing the electrical resistance (second embodiment), each film thickness is not particularly limited and, thus, it may be adjusted suitably according to a required electrical resistivity.

For example, the thickness of the Cu alloy film when it is used solely (monolayer) is preferably 600 nm or less, more preferably 450 nm or less, and still more preferably 300 nm or less, because the wiring shape and the residues may cause problems when the film is too thick. Further, in order to obtain outstanding oxidation-resistant improvement effects, it is preferably 50 nm or more, more preferably 100 nm or more, still more preferably 150 nm or more.

The total thickness of the Cu alloy interconnection film when using the laminated structure of the first layer and the second layer is approximately 100 nm or more, and more preferably 150 nm or more, while it being preferably 600 nm or less, and more preferably 200 nm or less. The film thickness of the first layer when constructed in the laminated structure is, in terms of maintaining the low electrical resistivity, preferably 100 nm or less, and more preferably 80 nm or less, and taking the oxidation-resistant improvement into consideration, it is preferably 5 nm or more, and more preferably 30 nm or more.

As described above, according to the Cu alloy interconnection film which demonstrates the effects excelling in the oxidation resistance, the oxidation-resistant improvement effects can be remarkably enhanced by applying a heat treatment after the film formation. This is considered to be because of the heat treatment after the film formation facilitating the concentration of the alloy element(s) at the interface of the transparent conducting film.

The temperature of the heat treatment is necessarily 50° C. or higher, and more preferably 100° C. or higher, in order to form the concentrated layer by spreading and concentrating the alloy element(s) over the Cu alloy film surface. However, if the heat treatment temperature becomes too high, oxidization of Cu will be facilitated to form a thick Cu oxide film and, thus, the electrical resistance will be high, which leads to exceeding a heat-resistant temperature of the resin substrate. Therefore, the heat treatment temperature is preferably less than 200° C., and more preferably 170° C. or less.

The heat treatment time within the above temperature range is preferably within a range between approximately 30 seconds and 30 minutes (retention time) in terms of suppressing an excessive formation of the Cu oxide film while forming the concentrated layer.

The feature of the present invention is the Cu alloy interconnection film connected with the transparent conductive film (first embodiment), or the Cu alloy interconnection film comprised of a lamination of the first layer and the second layer (second embodiment) and, thus, other configurations are not limited in particular. Therefore, any known configuration typically used in the art of the touch-panel sensors may be adopted.

For example, a resistive touch-panel sensor can be manufactured as follows. After forming a transparent conductive film on a substrate, photoresist application, exposure, development, and etching are sequentially performed. After that, a Cu alloy film is formed, and photoresist application, exposure, development, and etching are again performed to form wiring. Then, an insulating film or the like which covers the wiring is formed to make an upper electrode. In addition, after forming a transparent conductive film on a substrate, photo lithography is performed similar to the upper electrode. Then, also similar to the upper electrode, wiring is formed from a Cu alloy film (if monolayer structure), and an insulating film which covers the wiring is then formed. Then, a microdot spacer or the like is formed to make a lower electrode. Subsequently, the upper electrode, the lower electrode, and a tail portion which is formed separately are pasted together to manufacture the touch-panel sensor.

As for the Cu alloy film, it is preferably formed by sputtering. By using sputtering, the Cu alloy film having almost the same composition as a sputtering target can be formed. Regarding the sputtering, any of sputtering methods, such as DC sputtering, RF sputtering, magnetron sputtering, and reactive sputtering, may be adopted, and formation conditions may be suitably determined.

For example, in order to form the Cu alloy film by sputtering, a sputtering target, which is made of the Cu alloy containing the predetermined amount of the oxidation resistance enhancing element(s) (at least one element selected from a group consisting of Ni, Zn, and Mn), and has the same composition as the desired Cu alloy film, can be used. In this way, a composition gap does not occur, and the Cu alloy film having the desired component composition can be formed. The composition of the sputtering target may be adjusted using the Cu alloy target having a different composition, or may be adjusted by carrying out a chip-on of a metal of the alloy element(s) onto a pure Cu target.

The target shape may be obtained by shaping the target into an arbitrary shape (e.g., a rectangular plate, a circular plate, or a doughnut-shaped plate) according to the shape and the structure of a sputtering device. The manufacturing method of the target includes a method of obtaining the target by manufacturing an ingot made of a Cu-base alloy with melting and casting, powder sintering, or spray forming, and a method of obtaining the target by manufacturing a preform (an intermediate body before a final precise object is obtained) made of a Cu-base alloy and, after that, refining the preform by a refining machine.

Moreover, when forming the Cu alloy film having the laminated structure of the first layer and the second layer, a layer of a material which constitutes the second layer is formed by sputtering to form the second layer, and the first layer is then formed thereon by sputtering to obtain the laminated structure.

The above transparent conductive film is not limited in particular and, what made of indium tin oxide (ITO) or indium zinc oxide (IZO) may be exemplary used. As for the material of the substrate (transparent substrate), for example, a glass material, a polyethylene terephthalate base material, a polycarbonate base material, or a polyamide base material is typically used, and may also be used for the above purposes. It may be preferable to use a film made of a polyethylene terephthalate base material, a polycarbonate base material, or a polyamide base material, which demonstrates heat stability in a process below 200° C., has a low material cost, and can be applied to roll-to-roll processing. In this invention, glass may be used for the substrate of the lower electrode which serves as a stationary electrode, and a film made of, for example, a polycarbonate base material, may be used for the substrate of the upper electrode which requires flexibility. The heat history applied to the film substrate is satisfactory if it is below the heat-resistant temperature of the film, but it is preferred to use a film having a heat resistance corresponding to a heat history of 100° C. or higher in terms of the adhesion enhancement.

The touch-panel sensor of the present invention may also be used as touch-panel sensors of, for example, a capacitive type or an ultrasonic surface acoustic wave type, other than the resistive type described above.

### EXAMPLES

Below, although the present invention will be described in detail while giving several examples, the invention is not to be limited by the following examples in any ways. The invention may be implemented in various ways within the scope which suits the aforementioned and after-mentioned meaning with suitable changes being made, and they are encompassed within the technical scope of the present invention.

### Example 1

Polyethylene terephthalate (PET) was used as a substrate, and a transparent conductive film (ITO: the film thickness is about 100 nm) was formed on the substrate surface by DC magnetron sputtering under the following sputtering conditions. A film formation of the transparent conductive film is carried out using a disk-shaped target having a diameter of 4 inches made of the same component composition as the transparent conductive film after once setting atmosphere in a chamber to ultimate vacuum (3×10⁻⁶ Torr) as a pre film formation process.

### Sputtering Conditions

Ar gas flow rate: 8 sccm

O₂ gas flow rate: 0.8 sccm

Sputtering power: 260 W

Substrate temperature: Room temperature

After forming the transparent conductive film, a Cu alloy film (the film thickness is about 200 nm) having a component composition shown in Table 1 was successively formed on the transparent conductive film surface under the following sputtering conditions by DC magnetron sputtering. The film formation is carried out using a disk-shaped target having a diameter of 4 inches made of the same component composition as each Cu alloy film after once setting atmosphere in a chamber to ultimate vacuum (3×10⁻⁶ Torr) as a pre film formation process. Note that the composition of the formed Cu alloy film was checked by ICP emission spectrometry.

### Sputtering Conditions

Ar gas flow rate: 30 sccm

Ar gas pressure: 20 mTorr

Sputtering power: 260 W

Substrate temperature: Room temperature

Here, a sample was obtained by forming the Cu alloy film.

### Oxidation Resistance

Using the Cu alloy film obtained as described above, a thickness of an oxide layer was measured after heat treatment under the following conditions. Specifically, the cross-section of the Cu alloy film was observed by TEM (magnification: ×1,500,000) to measure the film thickness of the oxide layer (in the thickness direction from the Cu alloy film surface) formed on the Cu alloy film surface (in the table, “After heat treatment at 150° C.”). In this example, if the film thickness of the oxide layer was less than 30 nm, it was evaluated as “∘ (which indicates “Successful” in the table),” and if 30 nm or more, evaluated as “x” (which indicates “Failed” in the table). Note that, for reference, a film thickness of the oxide layer before the heat treatment was also measured (in the table, “Before heat treatment at 150° C.”).

Humidity: 60%

Temperature: 150° C.

Retention time: 1 hour

Atmosphere: Atmospheric conditions

### Existence of Concentrated Layer on Cu Alloy Film Surface

After the heat treatment at 150° C., it was checked whether a concentrated layer is formed on each sample. In detail, it was checked whether the concentrated layer is formed on the Cu alloy film surface for each sample by an EDX line analysis at the interface along with TEM images. In this example, it was determined as “∘” if the concentrated layer was confirmed, and determined as “x” if the concentrated layer was not confirmed (in the table, “Concentrated layer”). The results are shown in Table 1.

TABLE 1

| | | Film Thickness of Oxide Layer (nm) | | | |
|---|---|---|---|---|---|
| | | Before Heat | After Heat | Successful/ | Concentrated |
| No. | Film Composition | Treatment at 150° C. | Treatment at 150° C. | Failed | Layer |
| 1 | Cu-0.1 at % Ni | <3 | 23 | ∘ | ∘ |
| 2 | Cu-0.5 at % Ni | <3 | 17 | ∘ | ∘ |
| 3 | Cu-1 at % Ni | <3 | 15 | ∘ | ∘ |
| 4 | Cu-2 at % Ni | <3 | 13 | ∘ | ∘ |
| 5 | Cu-5 at % Ni | <3 | 10 | ∘ | ∘ |
| 6 | Cu-10 at % Ni | <3 | 10 | ∘ | ∘ |
| 7 | Cu-40 at % Ni | <3 | 8 | ∘ | ∘ |
| 8 | Cu-0.1 at % Zn | <3 | 25 | ∘ | ∘ |
| 9 | Cu-0.5 at % Zn | <3 | 20 | ∘ | ∘ |
| 10 | Cu-1 at % Zn | <3 | 17 | ∘ | ∘ |
| 11 | Cu-2 at % Zn | <3 | 16 | ∘ | ∘ |
| 12 | Cu-5 at % Zn | <3 | 12 | ∘ | ∘ |
| 13 | Cu-10 at % Zn | <3 | 10 | ∘ | ∘ |
| 14 | Cu-40 at % Zn | <3 | 9 | ∘ | ∘ |
| 15 | Cu-0.1 at % Mn | <3 | 29 | ∘ | ∘ |
| 16 | Cu-0.5 at % Mn | <3 | 26 | ∘ | ∘ |
| 17 | Cu-1 at % Mn | <3 | 22 | ∘ | ∘ |
| 18 | Cu-2 at % Mn | <3 | 20 | ∘ | ∘ |
| 19 | Cu-5 at % Mn | <3 | 17 | ∘ | ∘ |
| 20 | Cu-10 at % Mn | <3 | 12 | ∘ | ∘ |
| 21 | Cu-40 at % Mn | <3 | 10 | ∘ | ∘ |
| 22 | Cu-0.1 at % Ni-0.1 at % Zn | <3 | 20 | ∘ | ∘ |
| 23 | Cu-0.1 at % Ni-0.1 at % Mn | <3 | 23 | ∘ | ∘ |
| 24 | Cu-0.1 at Zn-0.1 at % Mn | <3 | 24 | ∘ | ∘ |
| 25 | Cu-0.1 at % Ni-0.1 at % Zn-0.1 at % Mn | <3 | 19 | ∘ | ∘ |
| 26 | Cu-1 at % Ni-1 at % Zn | <3 | 14 | ∘ | ∘ |
| 27 | Cu-20 at % Ni-20 at % Zn | <3 | 8 | ∘ | ∘ |
| 28 | Cu-1 at % Ni-1 at % Mn | <3 | 14 | ∘ | ∘ |
| 29 | Cu-20 at % Ni-20 at % Mn | <3 | 8 | ∘ | ∘ |
| 30 | Cu-1 at Zn-1 at % Mn | <3 | 16 | ∘ | ∘ |
| 31 | Cu-20 at Zn-20 at % Mn | <3 | 9 | ∘ | ∘ |
| 32 | Cu-1 at % Ni-1 at % Zn-1 at % Mn | <3 | 11 | ∘ | ∘ |
| 33 | Cu-13 at % Ni-13 at % Zn-13 at % Mn | <3 | 8 | ∘ | ∘ |
| 34 | Cu | <3 | 35 | x | x |
| 35 | Cu-5 at % Ca | <3 | 37 | x | x |
| 36 | Cu-5 at % Ge | <3 | 33 | x | x |
| 37 | Cu-5 at % Mg | <3 | 40 | x | x |

*Film Composition includes alloy component(s), and the remainder containing Cu and inevitable impurities

Nos. 1-21 are examples of the Cu alloy film containing one element selected from the group consisting of Ni, Zn, and Mn (the remainder contains Cu and inevitable impurities). Nos. 22-33 are examples of the Cu alloy film containing at least two elements selected from the group consisting of Ni, Zn, and Mn (the remainder contains Cu and inevitable impurities). Since any of these samples had the content of the alloy elements defined in the claims and they were created by controlling the sputtering conditions within a desirable range of the present invention, they excelled in the oxidation resistance.

On the other hand, Nos. 34-37 are examples of pure Cu (No. 34) which do not contain any of the alloy elements, and Cu alloy films (Nos. 35-37) containing elements other than the alloy elements defined in the claims. Thus, the oxidation resistance was poor although the sputtering conditions were controlled within the desirable range of the present invention.

### Example 2

Polyethylene terephthalate was used as a substrate similar to Example 1, and a transparent conductive film (ITO: the film thickness is about 100 nm) was formed on the substrate surface. After forming the transparent conductive film, a second layer (pure Cu or a Cu alloy: the film thickness is about 200 nm) having the component composition shown in Table 2 was successively formed on the transparent conductive film surface by DC magnetron sputtering similar to Example 1. Successively on the surface of the second layer, a first layer having a component composition shown in Table 2 was formed by DC magnetron sputtering similar to Example 1 to form a Cu alloy film which has a laminated structure of the first layer and the second layer.

For the Cu alloy films obtained as described above, the oxidation resistance and the existence of the concentrated layer were evaluated similar to Example 1. The results are shown in Table 2.

TABLE 2

| | First Layer | | Second Layer | Film Thickness of Oxide Layer (nm) | | | |
|---|---|---|---|---|---|---|---|
| | Film | Film | Film | Before Heat | After Heat | Successful/ | Concentrated |
| No. | Composition | Thickness (nm) | Composition | Treatment at 150° | Treatment at 150° | Failed | Layer |
| 101 | Cu—1.0 at % Ni | 6 | Cu | <3 | 15 | ◯ | ◯ |
| 102 | Cu—1.0 at % Ni | 10 | Cu | <3 | 14 | ◯ | ◯ |
| 103 | Cu—1.0 at % Ni | 50 | Cu | <3 | 15 | ◯ | ◯ |
| 104 | Cu—1.0 at % Ni | 100 | Cu | <3 | 16 | ◯ | ◯ |
| 105 | Cu—1.0 at % Ni | 50 | Cu—0.1 at % Ni | <3 | 15 | ◯ | ◯ |
| 106 | Cu—1.0 at % Zn | 5 | Cu | <3 | 18 | ◯ | ◯ |
| 107 | Cu—1.0 at % Zn | 10 | Cu | <3 | 17 | ◯ | ◯ |
| 108 | Cu—1.0 at % Zn | 50 | Cu | <3 | 17 | ◯ | ◯ |
| 109 | Cu—1.0 at % Zn | 100 | Cu | <3 | 18 | ◯ | ◯ |
| 110 | Cu—1.0 at % Zn | 50 | Cu—0.1 at % Zn | <3 | 16 | ◯ | ◯ |
| 111 | Cu—1.0 at % Mn | 5 | Cu | <3 | 24 | ◯ | ◯ |
| 112 | Cu—1.0 at % Mn | 10 | Cu | <3 | 21 | ◯ | ◯ |
| 113 | Cu—1.0 at % Mn | 50 | Cu | <3 | 22 | ◯ | ◯ |
| 114 | Cu—1.0 at % Mn | 100 | Cu | <3 | 21 | ◯ | ◯ |
| 115 | Cu—1.0 at % Mn | 50 | Cu—0.1 at % Mn | <3 | 22 | ◯ | ◯ |

*Film Composition includes alloy component(s), and the remainder containing Cu and inevitable impurities

Nos. 101-115 are examples of the Cu alloy films containing one element selected from the group consisting of Ni, Zn, and Mn as the first layer (the remainder contains Cu and inevitable impurities). Since these samples had the contents of the alloy elements defined in the claims and they were created by controlling the sputtering conditions within the desirable range of the present invention, they excelled in the oxidation resistance.

Note that, in Example 2, since the second layer (Cu and inevitable impurities, or 0.1 atom % of any of Ni, Zn and Mn, and the remainder containing Cu and inevitable impurities) having a lower electrical resistivity than the first layer was formed, each of the samples has the electrical resistivity of 10 μΩcm or lower.

In the meantime, the present inventors conducted careful research in order to provide a interconnection film excelling in adhesion properties to a transparent conductive film made of, for example, ITO, in addition to having a low electrical resistance required for touch-panel sensor wiring, as well as to provide a touch-panel sensor using the interconnection film.

It is particularly important for a touch-panel application to improve the adhesion properties between the transparent conductive film made of, for example, ITO, and the interconnection film. However, the adhesion between the interconnection film and the transparent conductive film is lower than adhesion between the interconnection film and the insulating film or adhesion between the interconnection film and the substrate, which have been examined for the conventional liquid crystal display applications. In addition, the heat history in the touch-panel manufacturing process is lower (less than 200° C.) than the heat history of a liquid crystal display manufacturing process. Therefore, the adhesion enhancement technique which has been examined for the liquid crystal display applications is not applicable to the touch-panel applications.

The results of the present inventors' further repeating examinations showed that the interconnection film which is directly connected to the transparent conductive film is preferred to be made of a Cu alloy containing at least one element selected from a group consisting of Ni, Zn, and Mn as alloy element(s) (adhesion enhancing element(s)). Specifically, it was found that the alloy element(s) (Ni, Zn, and/or Mn) contained in the Cu alloy forms a concentrated layer at an interface with the transparent conductive film, and the concentrated layer increases the adhesion properties. It can be considered that the concentrated layer is formed at the interface with the transparent conductive film so that the alloy element(s) (Ni, Zn, and/or Mn) exceeding a solid solubility limit in the Cu alloy due to heat treatment or the like are spread and concentrated. Here, the term “concentrated layer” as used herein refers to a formation of a concentrated layer area near the surface of the Cu alloy interconnection film (on a contact surface side with the transparent conductive film), where the concentrated layer area has an alloy content higher than an alloy content of the entire Cu alloy interconnection film (i.e., an average alloy concentration). The alloy element is at least one element selected from the group consisting of Ni, Zn, and Mn.

Hereinafter, one embodiment of the invention excelling in the adhesion properties to the transparent conductive film will be described in detail. A third embodiment of the invention is described next.

### Third Embodiment

### [Cu Alloy Containing Predetermined Amount of At Least One Alloy Element Selected From Group Consisting of Ni, Zn, and Mn: Monolayer]

In this embodiment, Cu contains a predetermined amount of one element selected from a group consisting of Ni, Zn, and Mn as adhesion enhancing element(s) to enhance the adhesion properties.

These elements dissolve in copper but do not dissolve in copper oxide. It can be considered that, if the Cu alloy where these elements are dissolved oxidizes by heat treatment in the film formation process or the like, the elements spread and concentrate at grain boundaries or at the interface, and this concentrated layer improves the adhesion properties to the transparent conductive film. Such a formation of the concentrated layer secure sufficient adhesion properties even if the Cu alloy interconnection film is connected with the transparent conductive film directly.

Among the adhesion enhancing elements described above, Ni and Zn are preferred and Ni is more preferred. This is because Ni is an element of which a concentrating phenomenon can be discovered very strongly at the interface described above, resulting in a great enhancement of the adhesion.

The concentrated layer where at least one element selected from the group consisting of Ni, Zn, and Mn is concentrated at the interface can be obtained preferably by heat treatment at or above about 100° C. for 1 minute or longer after the Cu alloy film formation by sputtering. This is because such heat treatment spreads the alloy element(s) at the interface and makes them easier to concentrate. Upper limits of the heat-treatment conditions are not limited in particular as long as the desired concentrated layer can be obtained, and the limit can be suitably adjusted in accordance with the heat resistance of the substrate, the efficiency of the process, etc.

Note that the heat treatment described above may be carried out for the purpose of a formation of the concentrated layer, or may be carried out such that the heat history after the formation of the Cu alloy film (e.g., a process of sputtering or to bake the resist layer) meets the temperature and the time described above.

The content of the element(s) is 0.1 atom % or more in a total amount. Sufficient adhesion properties to the transparent conductive film cannot be obtained, if the content of the element(s) is below 0.1 atom %. The more content of the element(s) the more effects in the improvement of adhesion properties can be obtained. However, if the total content of the element(s) exceeds 6 atom %, a microfabrication will be difficult due to an increase of undercut at the time of etching into the wiring shape or a generation of residues and, in addition, the electrical resistivity of the Cu alloy interconnection film itself will be higher to increase signal delays and power loss. As described above, in terms of the adhesion properties, a preferable lower limit of the total content of the element(s) may be 0.3 atom %, more preferably 0.5 atom %, and still more preferably 1.0 atom %. In terms of the electrical resistivity or the like, a preferable upper limit of the total content may be 5.0 atom %, more preferably 4.0 atom %, and still more preferably 2.0 atom %.

The independent content of each element may vary according to kind of element as follows. This is because influences on the adhesion properties and the electrical resistance changes with the element kind.

In order to demonstrate the sufficient adhesion properties, Ni is necessarily contained by 0.1 atom % or more, preferably 0.3 atom % or more, and still more preferably 0.5 atom % or more. On the other hand, since an excessive addition of Ni may cause processing difficulties and may increase the electrical resistivity too high, the Ni content should be 6 atom % or less, preferably 4.0 atom % or less, and more preferably 2.0 atom % or less.

In order to demonstrate the sufficient adhesion properties, Zn is necessarily contained by 0.1 atom % or more, preferably 0.3 atom % or more, and still more preferably 0.5 atom % or more. On the other hand, since an excessive addition of Zn may cause processing difficulties and may increase the electrical resistivity too high, the Zn content should be 6 atom % or less, preferably 4.0 atom % or less, and still more preferably 2.0 atom % or less.

In order to demonstrate the sufficient adhesion properties, Mn is necessarily contained by 0.1 atom % or more, preferably 0.3 atom % or more, and still more preferably 0.5 atom % or more. On the other hand, since an excessive addition of Mn may cause processing difficulties and may increase the electrical resistivity too high, the Mn content should be 1.9 atom % or less, preferably 1.5 atom % or less, and still more preferably 1.0 atom % or less.

The desirable range of Ni and Zn when at least two or more of the elements are contained is as described above. The Mn content when at least Mn is contained is [((6−x)×2)/6] atom % or less (here, x is the total amount of addition of Ni and Zn). Further, according to the upper limit of the total content, it is preferably [((5.0−x)×1.9)/6] atom % or less, more preferably [((4.0−x)×1.9)/6] atom % or less, and still more preferably [((2.0−x)×1.9)/6] atom % or less.

The Cu alloy interconnection film used for the invention contains the above element(s) and the remainder contains Cu and inevitable impurities. The content of each alloy element in the Cu alloy interconnection film can be calculated, for example, by ICP emission spectrometry.

In the present invention, the above Cu alloy interconnection film may be used alone as the connecting material. Alternatively, onto a Cu alloy interconnection film (hereinafter, may be referred to as a “first layer”) containing the above element, a Cu alloy interconnection film (hereinafter, may be referred to as a “second layer”) of which electrical resistivity is lower than the first layer is laminated (a fourth embodiment), where the second layer is laminated on the opposite surface of the first layer from the contact surface thereof with the transparent conductive film. Hereinafter, the fourth embodiment of the invention is described.

### Fourth Embodiment

[Cu Alloy Interconnection film Comprising Cu Alloy (First Layer) Containing Predetermined Amount of At Least One Element Selected From Group Consisting of Ni, Zn, And Mn, and Second Layer Made of Cu Alloy Having Lower Electrical Resistivity Than First Layer: Laminated Structure]

The Cu alloy interconnection film (first layer) which directly contacts the transparent conductive film is made of a Cu alloy containing the element(s) (at least one selected from the group consisting of Ni, Zn, and Mn) which contributes to the adhesion enhancement similar to the third embodiment of the present invention. Thus, the adhesion properties of the interconnection film with the transparent conductive film also improve. However, the electrical resistivity will also increase with the adhesion properties, as the added amount of the alloy element(s) increases. For this reason, by laminating the second layer having a lower electrical resistivity than the first layer onto the first layer, a reduction of the electrical resistivity of the entire Cu alloy interconnection film can be achieved (refer to FIG. 2). Thus, by constructing the Cu alloy interconnection film into the laminated structure of the first layer and the second layer, the original characteristic of Cu which is low in the electrical resistivity is effectively and maximally exerted and, at the same time, the adhesion properties to the transparent conductive film that was a disadvantage of Cu can be further enhanced.

The term “Cu alloy having the lower electrical resistivity than the first layer” which constitutes the second layer also includes pure Cu as long as appropriately controlling the kind(s) and/or the content of the alloy element(s) so that the second layer is lower in the electrical resistivity than the first layer made of the Cu alloy containing the adhesion enhancing element(s). The element with the low electrical resistivity (preferably, as low as pure Cu) can be easily selected from known elements with reference to values or the like described in literatures. However, even for a high electrical resistivity element, since the electrical resistivity can be lowered if the content is lessened (approximately 0.05 to 1 atom %), the alloy elements applicable to the second layer are not necessarily limited to elements with low electrical resistivity. More specifically, in terms of suppressing the signal delays and/or the power loss due to the wiring resistance in a touch panel, the electrical resistivity of the second layer is preferably 11 μΩcm or lower, more preferably 8.0 μΩcm or lower, and still more preferably 5.0 μΩcm or lower.

When such a second layer is laminated onto the first layer to construct the Cu alloy interconnection film, since the electrical resistivity can be reduced by the second layer, the content of the adhesion enhancing element(s) of the first layer can be increased more than the third embodiment, resulting in more enhanced adhesion properties. Thus, since the electrical resistivity of the Cu alloy interconnection film having the laminated structure of the first layer and the second layer is based on the second layer of the low electrical resistivity, it allows the amount of the adhesion enhancing element to increase compared with the case of the monolayer. Therefore, in terms of enhancing the adhesion properties between the first layer and the transparent conductive film, the Cu alloy of the first layer necessarily contains at least one element selected from the group consisting of Ni, Zn, and Mn by 0.1 atom % or more, preferably 0.5 atom % or more, and still more preferably 1.0 atom % or more as the total amount. However, as for the upper limit, the Cu alloy of the first layer can contain the element(s) up to 30 atom % or less, preferably 20 atom % or less, and more preferably 15 atom % or less as the total amount (the remainder substantially contains Cu and inevitable impurities).

As described above, the Cu alloy interconnection film of the present invention is comprised of the Cu alloy monolayer containing the adhesion enhancing element(s) (third embodiment), or in terms of enhancing the adhesion properties and reducing the electrical resistance, it is constructed in the laminated structure of the first layer and the second layer (fourth embodiment). However, each film thickness is not limited in particular, and it may be suitably adjusted according to the adhesion properties and the electrical resistivity which are demanded.

For example, if the Cu alloy film is used alone (monolayer), since the wiring resistance may become high when the film is too thin. Therefore, the thickness may preferably be 50 nm or more, more preferably 70 nm or more, and still more preferably 100 nm or more.

Whereas, if using the Cu alloy interconnection film as the laminated structure of the first layer and the second layer, a preferable total thickness is approximately 100 nm or more and more preferably 200 nm or more, while preferably being 600 nm or less and more preferably 450 nm or less. In addition, in terms of securing the low electrical resistivity and the high adhesion properties, the thickness of the first layer when having the laminated structure is preferably 100 nm or less and more preferably 50 nm or less and, taking the enhancement of the adhesion properties into consideration, it is preferably 5 nm or more and more preferably 10 nm or more.

As described above, the Cu alloy interconnection film which demonstrates the excellent adhesion effects can acquire a dramatically enhanced adhesion by applying heat treatment after the film formation. This is considered to be because the concentration of the alloy element(s) is facilitated at the interface of the transparent conducting film by the heat treatment after the film formation.

The above heat treatment conditions act more effectively on the enhancement of the adhesion as the temperature is higher and the retention time is longer. However, the heat treatment temperature needs to be below a heat-resistant temperature of the substrate, and if the retention time is too long, a productivity of the touch panel will be reduced. Therefore, the heat treatment conditions are approximately within a range of 100 to 230° C. in the temperature and 1 to 30 minutes in the retention time.

Such a heat treatment may be carried out for the purpose of a further improvement in the adhesion properties, or may be carried out such that the heat history after the formation of the Cu alloy interconnection film (first layer) meets the temperature and the time described above.

The feature of the present invention is the Cu alloy interconnection film connected with the transparent conductive film (third embodiment), or the Cu alloy interconnection film comprised of the lamination of the first layer and the second layer (fourth embodiment), and other configurations of the invention are not limited in particular and may adopt any known configuration which is typically used in the art of the touch-panel sensors.

### Examples

### Example 3

A transparent conductive film (ITO or IZO: the film thickness is about 100 nm) was formed under similar conditions to Example 1.

After forming the transparent conductive film, a Cu alloy film (the film thickness is about 200 nm) having a component composition shown in Table 3 under sputtering conditions similar to Example 1 was successively formed by DC magnetron sputtering on the surface of the transparent conductive film.

Using the Cu alloy film thus obtained, the existence of a concentrated layer, adhesion properties, and electrical resistivity were examined under the following conditions after a heat treatment at 150° C. for 30 minutes.

### Existence of Concentrated Layer at Interface Between Transparent Conductive Film and Cu Alloy Film

After the heat treatment, it was checked whether or not the concentrated layer was formed. In detail, it was checked whether the concentrated layer was formed at the interface between the transparent conductive film and the Cu alloy film for each sample after the heat treatment, by TEM images and an EDX line analysis of the interface. In this example, if the existence of the concentrated layer was confirmed, it is indicated as “∘,” and if not confirmed, it is indicated as “x.”

### Adhesion Properties

The adhesion properties were evaluated by a stripping test with an adhesive tape. In detail, a total of 25 grids (5×5) each having a 1 mm side was created on the surface of the Cu alloy film by a cutter knife. Note that a cut depth by the cutter knife reaches the transparent conductive film, but the transparent conductive film is not cut. Subsequently, a transparent adhesive tape (Scotch® #600 available from the Sumitomo 3M Limited) was firmly stuck on these grids, and then, the tape was peeled off without hesitation at a peeling angle of 60°. Then, the number of grids which were not abraded by the tape was counted, and a ratio of the abraded grid over the entire grids was calculated (a film residual ratio). Measurements were performed three times on each sample, and an average of the three measurements was used as an adhesion rate of the sample.

In this example, if the adhesion rate is less than 80%, it is indicated as “x,” if 80% or more, it is indicated as “Δ,” if 90% or more, it is indicated as “∘,” and if 95% or more, it is indicated as “!” If 80% or more, the sample was determined to be a “Successful” sample (indicated as “∘” in the table).

### Electrical Resistivity

Each Cu alloy film described above was processed into a line pattern of a 100 μm line width and 4.0 mm line length by photo lithography and etching (mixed acid) in order to evaluate the electrical resistance. The electrical resistance was measured in electrical resistivity by the four-terminal method. If the electrical resistivity was 11 μΩcm or less, it is indicated as “∘,” and if exceeding 11 μΩcm, it is indicated as “x.” In this example, “∘” is determined to be a good electrical resistivity.

The adhesion properties and the electrical resistivity were similarly measured for the samples (No. 236 and No. 237) where a pure Cu film was formed instead of the Cu alloy film as a reference example. These results are described together in Table 3 below.

TABLE 3

| | | Adhesion Properties | | | | |
|---|---|---|---|---|---|---|
| | | to Transparent | | | | |
| | | Conductive Film | | | Electrical | |
| | | | Adhesion Rate | Concentrated | Resistivity | Successful/ |
| No. | Film Composition | Film Type | (%) | Layer | (μΩcm) | Failed |
| 201 | Cu—0.1 at % Ni | ITO | 95% | ◯ | 2.2 | ◯ |
| 202 | Cu—0.5 at % Ni | ITO | 100% | ◯ | 2.7 | ◯ |
| 203 | Cu—1.0 at % Ni | ITO | 100% | ◯ | 3.5 | ◯ |
| 204 | Cu—1.0 at % Ni | IZO | 100% | ◯ | 3.5 | ◯ |
| 205 | Cu—2.0 at % Ni | ITO | 100% | ◯ | 4.8 | ◯ |
| 206 | Cu—5.0 at % Ni | ITO | 100% | ◯ | 9.0 | ◯ |
| 207 | Cu—6.0 at % Ni | ITO | 100% | ◯ | 10.4 | ◯ |
| 208 | Cu—7.0 at % Ni | ITO | 100% | ◯ | 11.7 | X |
| 209 | Cu—0.1 at % Zn | ITO | 87% | ◯ | 2.3 | ◯ |
| 210 | Cu—0.5 at % Zn | ITO | 95% | ◯ | 2.9 | ◯ |
| 211 | Cu—1.0 at % Zn | ITO | 100% | ◯ | 3.6 | ◯ |
| 212 | Cu—1.0 at % Zn | IZO | 100% | ◯ | 3.6 | ◯ |
| 213 | Cu—2.0 at % Zn | ITO | 100% | ◯ | 5.0 | ◯ |
| 214 | Cu—5.0 at % Zn | ITO | 100% | ◯ | 9.5 | ◯ |
| 215 | Cu—6.0 at % Zn | ITO | 100% | ◯ | 10.9 | ◯ |
| 216 | Cu—7.0 at % Zn | ITO | 100% | ◯ | 12.4 | X |
| 217 | Cu—0.1 at % Mn | ITO | 81% | ◯ | 2.5 | ◯ |
| 218 | Cu—0.3 at % Mn | ITO | 92% | ◯ | 3.5 | ◯ |
| 219 | Cu—0.5 at % Mn | ITO | 100% | ◯ | 4.3 | ◯ |
| 220 | Cu—1.0 at % Mn | ITO | 100% | ◯ | 6.6 | ◯ |
| 221 | Cu—1.5 at % Mn | ITO | 100% | ◯ | 8.9 | ◯ |
| 222 | Cu—1.9 at % Mn | ITO | 100% | ◯ | 10.7 | ◯ |
| 223 | Cu—2.0 at % Mn | ITO | 100% | ◯ | 11.1 | X |
| 224 | Cu—0.1 at % Ni—0.1 at % Zn | ITO | 92% | ◯ | 2.5 | ◯ |
| 225 | Cu—0.1 at % Ni—0.1 at % Mn | ITO | 90% | ◯ | 2.7 | ◯ |
| 226 | Cu—0.1 at Zn—0.1 at % Mn | ITO | 90% | ◯ | 2.7 | ◯ |
| 227 | Cu—0.1 at % Ni—0.1 at % Zn—0.1 at % Mn | ITO | 92% | ◯ | 2.9 | ◯ |
| 228 | Cu—1.0 at % Ni—1.0 at % Zn | ITO | 100% | ◯ | 5.0 | ◯ |
| 229 | Cu—3.0 at % Ni—3.0 at % Zn | ITO | 100% | ◯ | 10.7 | ◯ |
| 230 | Cu—1.0 at % Ni—0.4 at % Mn | ITO | 100% | ◯ | 5.3 | ◯ |
| 231 | Cu—3.0 at % Ni—1.0 at % Mn | ITO | 100% | ◯ | 10.6 | ◯ |
| 232 | Cu—1.0 at % Zn—0.4 at % Mn | ITO | 100% | ◯ | 5.5 | ◯ |
| 233 | Cu—3.0 at % Zn—1.0 at % Mn | ITO | 100% | ◯ | 10.8 | ◯ |
| 234 | Cu—0.5 at % Ni—0.5 at % Zn—0.4 at % Mn | ITO | 100% | ◯ | 5.4 | ◯ |
| 235 | Cu—1.5 at % Ni—1.5 at % Zn—1.0 at % Mn | ITO | 100% | ◯ | 10.8 | ◯ |
| 236 | Cu | ITO | 0% | X | 2.1 | X |
| 237 | Cu | IZO | 0% | X | 2.1 | X |
| 238 | Cu—6.0 at % Ge | ITO | 0% | X | 10.2 | X |

*Film Composition includes alloy component(s), and the remainder containing Cu and inevitable impurities

Nos. 201-207, Nos. 209-215, and Nos. 217-222 are samples of the Cu alloy film which satisfy the requirements of the invention which contain one element selected from the group consisting of Ni, Zn, and Mn (the remainder contains Cu and inevitable impurities). Moreover, Nos. 224-235 are samples of the Cu alloy film which satisfy the requirements for the invention which contain at least two elements selected from the group consisting of Ni, Zn, and Mn (the remainder contains Cu and inevitable impurities).

Since these samples had the content of the alloy element(s) defined in the claims and were created by controlling the sputtering conditions within the desirable range of the invention, they excelled in the adhesion properties, and the electrical resistivity thereof was controlled low as well. In these samples, the adhesion rates were improved as the adding amount of the alloy element(s) increased and, in addition, tendencies of the electrical resistivity increasing were also observed.

On the other hand, Nos. 208, 216, and 223 had high electrical resistivity because the content of the alloy element(s) deviated from the range defined in the claims. Moreover, Nos. 236 and 237 are samples of pure Cu which does not contain any of the alloy elements, but no concentrated layer was formed and the adhesion properties were poor regardless of the sputtering conditions being controlled within the desirable range of the invention. No. 238 is a sample which uses an alloy element not defined in the invention and, therefore, no concentrated layer was formed and the adhesion properties were poor.

### Example 4

Polyethylene terephthalate was used as a substrate similar to the Example 3, and a transparent conductive film (ITO: the film thickness is about 100 nm) was formed on the substrate surface. After forming the transparent conductive film, a Cu alloy film (a first layer: refer to Table 4 for its film thickness) having a component composition shown in Table 4 similar to Example 3 was successively formed on the surface of the transparent conductive film. Successively on the surface of the first layer, a second layer (pure-Cu or an Cu alloy: the film thickness is about 300 nm) having a component composition shown in Table 4 was formed by DC magnetron sputtering under the same sputtering conditions as the first layer (the Cu alloy film of Example 3) to form a Cu alloy film having a laminated structure of the first layer and the second layer.

For the Cu alloy films obtained as described above, each characteristic was evaluated similar to Example 3. The results are shown in Table 4.

TABLE 4

| | Film Structure | | | | | | |
|---|---|---|---|---|---|---|---|
| | First Layer | | | Second Layer | | | |
| | | Film | | Film | Concentrated | Adhesion | Successful/ |
| No. | Film Composition | Thickness | | Composition | Layer | Rate (%) | Failed |
| 301 | Cu—0.1 at % Ni | 5 | nm | Cu | ◯ | 90% | ◯ |
| 302 | Cu—0.1 at % Ni | 20 | nm | Cu | ◯ | 94% | ◯ |
| 303 | Cu—0.1 at % Ni | 80 | nm | Cu | ◯ | 95% | ◯ |
| 304 | Cu—0.1 at % Ni | 100 | nm | Cu | ◯ | 95% | ◯ |
| 305 | Cu—10 at % Ni | 5 | nm | Cu | ◯ | 97% | ◯ |
| 306 | Cu—10 at % Ni | 20 | nm | Cu | ◯ | 100% | ◯ |
| 307 | Cu—10 at % Ni | 80 | nm | Cu | ◯ | 100% | ◯ |
| 308 | Cu—10 at % Ni | 100 | nm | Cu | ◯ | 100% | ◯ |
| 309 | Cu—30 at % Ni | 5 | nm | Cu | ◯ | 98% | ◯ |
| 310 | Cu—30 at % Ni | 20 | nm | Cu | ◯ | 100% | ◯ |
| 311 | Cu—30 at % Ni | 80 | nm | Cu | ◯ | 100% | ◯ |
| 312 | Cu—30 at % Ni | 100 | nm | Cu | ◯ | 100% | ◯ |
| 313 | Cu—10 at % Ni | 5 | nm | Cu—0.1 at % Ni | ◯ | 96% | ◯ |
| 314 | Cu—10 at % Ni | 20 | nm | Cu—0.1 at % Ni | ◯ | 100% | ◯ |
| 315 | Cu—10 at % Ni | 80 | nm | Cu—0.1 at % Ni | ◯ | 100% | ◯ |
| 316 | Cu—10 at % Ni | 100 | nm | Cu—0.1 at % Ni | ◯ | 100% | ◯ |
| 317 | Cu—0.1 at % Zn | 5 | nm | Cu | ◯ | 82% | ◯ |
| 318 | Cu—0.1 at % Zn | 20 | nm | Cu | ◯ | 86% | ◯ |
| 319 | Cu—0.1 at % Zn | 80 | nm | Cu | ◯ | 86% | ◯ |
| 320 | Cu—0.1 at % Zn | 100 | nm | Cu | ◯ | 88% | ◯ |
| 321 | Cu—10 at % Zn | 5 | nm | Cu | ◯ | 97% | ◯ |
| 322 | Cu—10 at % Zn | 20 | nm | Cu | ◯ | 100% | ◯ |
| 323 | Cu—10 at % Zn | 80 | nm | Cu | ◯ | 100% | ◯ |
| 324 | Cu—10 at % Zn | 100 | nm | Cu | ◯ | 100% | ◯ |
| 825 | Cu—30 at % Zn | 5 | nm | Cu | ◯ | 97% | ◯ |
| 326 | Cu—30 at % Zn | 20 | nm | Cu | ◯ | 100% | ◯ |
| 327 | Cu—30 at % Zn | 80 | nm | Cu | ◯ | 100% | ◯ |
| 328 | Cu—30 at % Zn | 100 | nm | Cu | ◯ | 100% | ◯ |
| 329 | Cu—0.1 at % Mn | 5 | nm | Cu | ◯ | 80% | ◯ |
| 330 | Cu—0.1 at % Mn | 20 | nm | Cu | ◯ | 80% | ◯ |
| 331 | Cu—0.1 at % Mn | 80 | nm | Cu | ◯ | 83% | ◯ |
| 332 | Cu—0.1 at % Mn | 100 | nm | Cu | ◯ | 83% | ◯ |
| 333 | Cu—10 at % Mn | 5 | nm | Cu | ◯ | 91% | ◯ |
| 334 | Cu—10 at % Mn | 20 | nm | Cu | ◯ | 100% | ◯ |
| 335 | Cu—10 at % Mn | 80 | nm | Cu | ◯ | 100% | ◯ |
| 336 | Cu—10 at % Mn | 100 | nm | Cu | ◯ | 100% | ◯ |
| 337 | Cu—30 at % Mn | 5 | nm | Cu | ◯ | 97% | ◯ |
| 338 | Cu—30 at % Mn | 20 | nm | Cu | ◯ | 100% | ◯ |
| 339 | Cu—30 at % Mn | 80 | nm | Cu | ◯ | 100% | ◯ |
| 340 | Cu—30 at % Mn | 100 | nm | Cu | ◯ | 100% | ◯ |
| 341 | Cu—0.1 at % Ni—0.1 at % Zn—0.1 at % Mn | 5 | nm | Cu | ◯ | 85% | ◯ |
| 342 | Cu—0.1 at % Ni—0.1 at % Zn—0.1 at % Mn | 20 | nm | Cu | ◯ | 90% | ◯ |
| 343 | Cu—0.1 at % Ni—0.1 at % Zn—0.1 at % Mn | 80 | nm | Cu | ◯ | 91% | ◯ |
| 344 | Cu—0.1 at % Ni—0.1 at % Zn—0.1 at % Mn | 100 | nm | Cu | ◯ | 90% | ◯ |
| 345 | Cu—10 at % Ni—10 at % Zn—10 at % Mn | 5 | nm | Cu | ◯ | 97% | ◯ |
| 346 | Cu—10 at % Ni—10 at % Zn—10 at % Mn | 20 | nm | Cu | ◯ | 100% | ◯ |
| 347 | Cu—10 at % Ni—10 at % Zn—10 at % Mn | 80 | nm | Cu | ◯ | 100% | ◯ |
| 348 | Cu—10 at % Ni—10 at % Zn—10 at % Mn | 100 | nm | Cu | ◯ | 100% | ◯ |

*Film Composition includes alloy component(s), and the remainder containing Cu and inevitable impurities

Nos. 301-340 are samples of the Cu alloy film containing one element selected from the group consisting of Ni, Zn, and Mn as the first layer (the remainder contains Cu and inevitable impurities). Nos. 341-348 are samples of the Cu alloy film containing at least two elements selected from the group consisting of Ni, Zn, and Mn as the first layer (the remainder contains Cu and inevitable impurities).

Since these samples have the contents of the alloy element(s) defined in the claims and they were created by controlling the sputtering conditions within the desirable range of the present invention, they excelled in the adhesion properties. Similar to Example 3, each of the samples demonstrates a tendency such that the adhesion properties improve as the adding amount of the alloy element(s) increases, and a tendency such that the adhesion properties also improve as the film becomes thicker was observed.

Note that, in Example 4, since the second layer (Cu and inevitable impurities, or 0.1 atom % of Ni and the remainder containing Cu and inevitable impurities) having a lower electrical resistivity than the first layer was formed, each of the samples has the electrical resistivity 11 μΩcm or lower.

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as critical, required, or essential features or elements of any or all the claims. The invention is defined solely by the appended claims including any amendments made during the pendency of this application and all equivalents of those claims as issued.

What is claimed is:

1. A interconnection film, having a transparent conductive film and connected with the transparent conductive film, the interconnection film comprising:
a first layer, excelling in oxidation resistance, and made of a Cu alloy containing at least one alloy element selected from a group consisting of Ni, Zn, and Mn by 0.1 to 40 atom % in a total amount; and
a second layer made of pure Cu or a Cu alloy mainly containing Cu, the Cu alloy having an electrical resistivity lower than the first layer,
wherein the interconnection film has a laminated structure of the first layer and the second layer, and
wherein at least one of the first layer and the second layer is connected with the transparent conductive film.

2. The interconnection film of claim 1, wherein the first layer contains at least one alloy element selected from the group consisting of Ni, Zn, and Mn by 0.1 to 30 atom % in a total amount, and the first layer is connected with the transparent conductive film.

3. The interconnection film of claim 1 or 2, wherein a thickness of the first layer is 5 to 100 nm.

4. A interconnection film having a transparent conductive film and connected with the transparent conductive film, wherein the interconnection film is made of a Cu alloy containing at least one alloy element selected from a group consisting of Ni, Zn, and Mn,
wherein, if containing one alloy element, Ni is contained by 0.1 to 6 atom %, or Zn is contained by 0.1 to 6 atom %, or Mn is contained by 0.1 to 1.9 atom %, and
wherein, if containing two or more alloy elements, the alloy elements are contained by 0.1 to 6 atom % in a total amount (wherein, Mn is contained by [((6−x)×2)/6] atom % or less if Mn is contained; here, x is a total adding amount of Ni and Zn in the formula).

5. A touch-panel sensor comprising the interconnection film of any one of claims 1, 2, and 4.

6. The touch-panel sensor of claim 5, wherein the transparent conductive film is formed on a film substrate.

7. A sputtering target for forming the interconnection film of claim 1, the sputtering target containing at least one alloy element selected from the group consisting of Ni, Zn, and Mn by 0.1 to 40 atom % in total, wherein the remainder containing Cu and inevitable impurities.

8. A sputtering target for forming the interconnection film of claim 2, the sputtering target containing at least one alloy element selected from the group consisting of Ni, Zn, and Mn by 0.1 to 30 atom % in total, wherein the remainder containing Cu and inevitable impurities.

9. A method of manufacturing the interconnection film of claim 1 or 2, comprising:
forming the interconnection film containing at least one alloy element selected from the group consisting of Ni, Zn, and Mn by 0.1 to 30 atom % in total, wherein the remainder containing Cu and inevitable impurities; and
then heating the interconnection film at a temperature below 200° C. for 30 seconds or longer.
